(19) United States
(12) Patent Application Publication
(10) Pub. No.: US 2026/0136933 A1
(43) Pub. Date: May 14, 2026

(54) MICROCHIP PACKAGE WITH INTEGRATED COLD PLATE

(71) Applicant: OpenAI OpCo, LLC., San Francisco, CA (US)

(72) Inventors: Reza Khiabani, San Mateo, CA (US); Teck Gyu Kang, Saratoga, CA (US)

(73) Assignee: OpenAI OpCo, LLC., San Francisco, CA (US)

(21) Appl. No.: 18/945,993

(22) Filed: Nov. 13, 2024

(51) Int. Cl. H01L 23/46; H01L 21/50; H01L 23/00

(52) U.S. Cl. CPC H10W 40/40; H10W 95/00; H10W 90/731

(57) ABSTRACT

The present technology pertains to a packaged microchip that includes an integrated cold plate. The packaged microchip includes a substrate and a die, which can be a semiconductor chip on which an integrated circuit has been fabricated. The die has a thermal-interface surface on which a thermal interface material (TIM) is provided. The integrated cold plate is fixed to the substrate. The cold plate has a die surface and a heat-dissipating surface. The die surface contacts the TIM such that the TIM is sandwiched between the die and the heat-removal member. The heat-removal member is monolithic and is configured to remove heat from the die via heat transfer from the heat-removal member to a fluid.

### BACKGROUND

Lidless and lidded packaging are two types of packaging that can be used for microchips. Lidded packaging involves a protective lid or cover that seals the microchip within a package. This lid can be made of materials like ceramic or plastic. The lid provides physical protection against environmental factors such as dust, moisture, and mechanical stress.

Lidless packaging excludes the protective cover. The die is exposed and can be mounted directly on a substrate or within a package that allows for easier access to the die itself. Lidless designs can be more compact and lighter, making them suitable for space-constrained applications.

For both lidless and lidded packaging of microchips, the packaged microchips can be mounted to a printed circuit board (PCB), and after the packaged microchip has been mounted on the PCB, a cold plate can be provided to remove heat.

### BRIEF DESCRIPTION OF THE SEVERAL VIEWS OF THE DRAWINGS

Details of one or more aspects of the subject matter described in this disclosure are set forth in the accompanying drawings and the description below. However, the accompanying drawings illustrate only some typical aspects of this disclosure and are therefore not to be considered limiting of its scope. Other features, aspects, and advantages will become apparent from the description, the drawings, and the claims.

FIG. 1A illustrates a first example of a packaged microchip with an integrated cold plate, in accordance with some embodiments.

FIG. 1B illustrates a second example of a packaged microchip with an integrated cold plate, in accordance with some embodiments.

FIG. 1C illustrates a third example of a packaged microchip with an integrated cold plate, in accordance with some embodiments.

FIG. 2A illustrates cutaway side view for an example of an integrated cold plate with a fluid channel, in accordance with some embodiments.

FIG. 2B illustrates cutaway top view for an example of an integrated cold plate with a fluid channel, in accordance with some embodiments.

FIG. 3 illustrates an example of a packaged microchip with an integrated cold plate and a cold plate cover, in accordance with some embodiments.

FIGS. 4A-G illustrates the packaged microchip with integrated cold plate at respective states of assembly, in accordance with some embodiments.

FIG. 5 illustrates a method for assembling a packaged microchip with an integrated cold plate, in accordance with some embodiments.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

In contrast to lidless and lidded packaging designs for packaging microchips, the systems and methods disclosed herein provide improved heat removal by integrating a cold plate into the chip packaging. Whereas for lidless and lidded packaging designs a cold plate is only provided after the packaged microchips have been mounted to the printed circuit board (PCB), the integrated cold plate disclosed herein is part of the chip packaging, which reduces the thermal resistance between the cold plate and the die to provide improved heat removal.

Compared to lidded packaging designs, the systems and methods disclosed herein eliminate a thermal interface material (TIM) layer between the die and the cold plate, reducing the thermal resistance. For example, traditional lidded packaging designs can include a cold plate added on top of a lidded microchip package, but, in this case, the heat path passes through two TIM layers (e.g., a first TIM layer between the die and the lid and a second TIM layer between the lid and the cold plate). In contrast, for the systems and methods disclosed herein, the heat path includes only one TIM layer (e.g., a TIM layer between the die and the cold plate).

Compared to lidless packaging designs, the systems and methods disclosed herein reduce the thermal resistance by improving the uniformity of the thickness of the TIM layer which enables the TIM layer to be thinner. For example, the integrated cold plate can increase the rigidity of the chip packaging thereby reducing warping of the die. In contrast, a lack of rigidity in the lidless microchip package can result in more warping of the die. When a cold plate is placed on the traditional lidless package after it has been mounted to the PCB, the warping of the die can result in less uniformity in the distance between the die and the cold plate, increasing the average thickness of the TIM between the die and the cold plate. This increased thickness of the TIM increases the thermal resistance, degrading heat removal from the die.

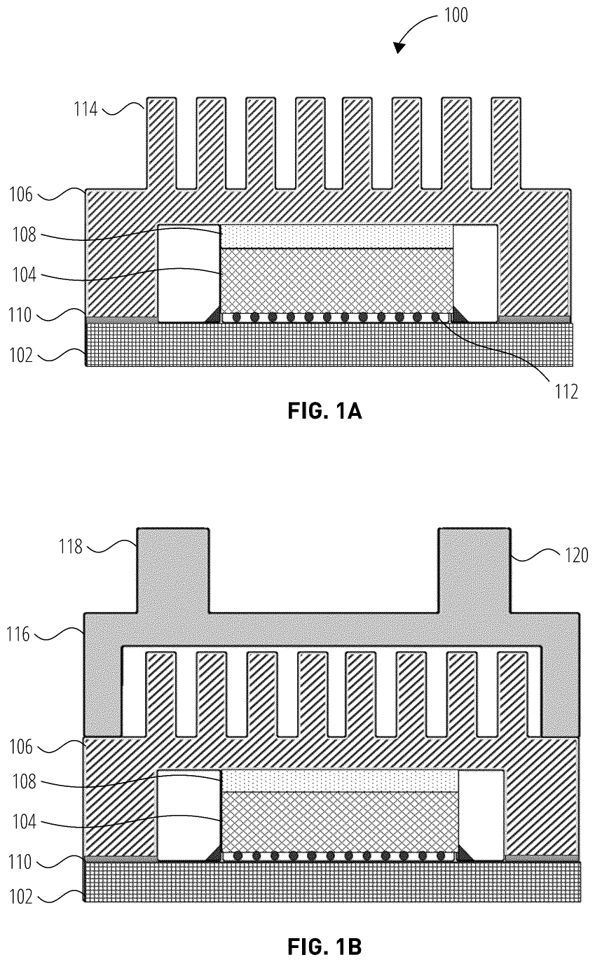

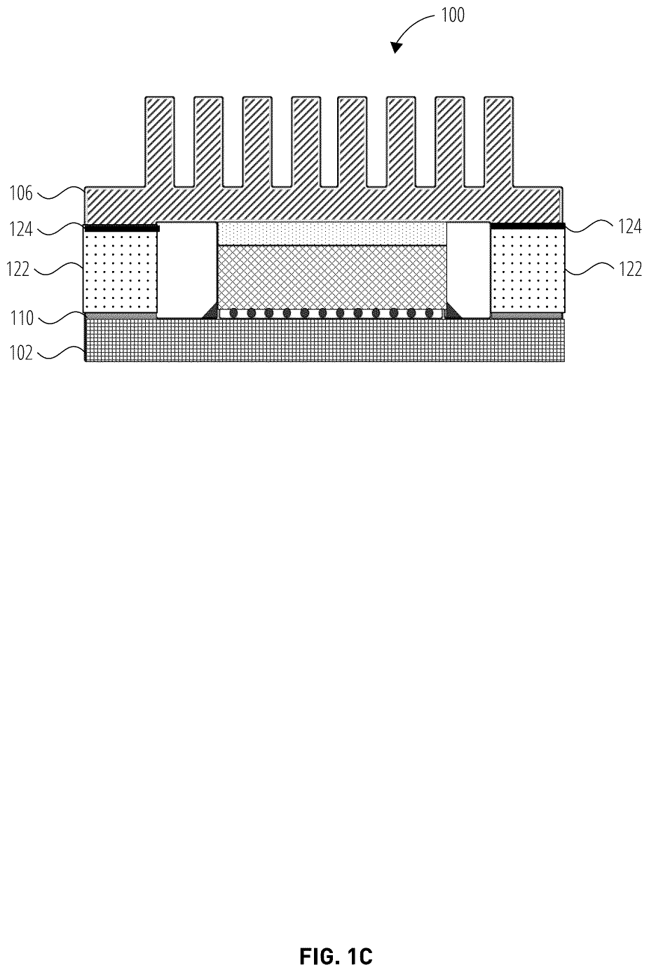

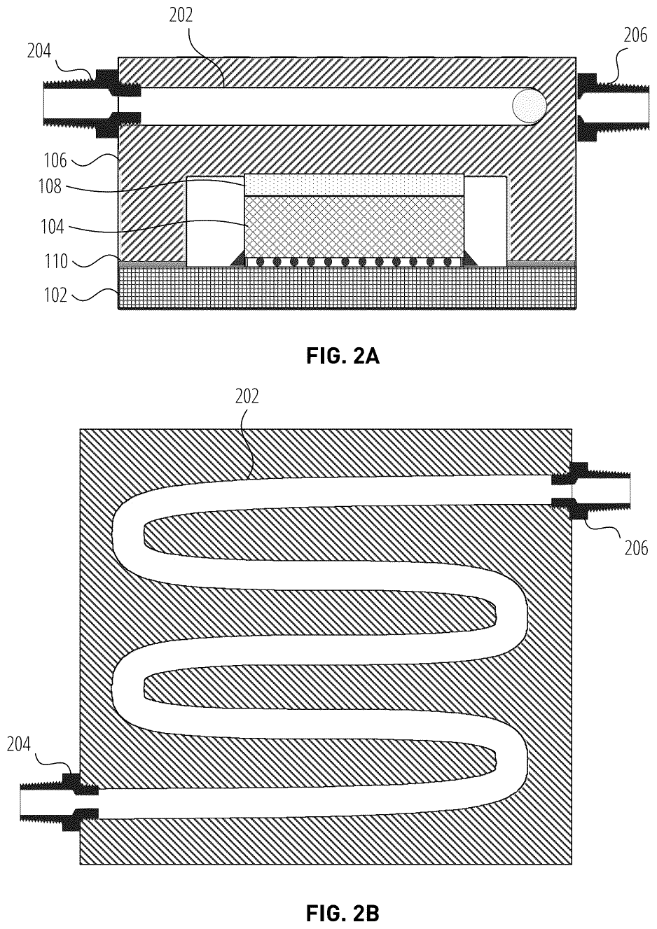

FIG. 1A illustrates an example of a packaged microchip 100 having a cold plate (e.g., cold plate 106) integrated with the chip packaging. Packaged microchip 100 can include a die 104 mounted on a substrate. Packaged microchip 100 can include cold plate 106, which is bonded to substrate 102 using adhesive 110, and cold plate 106 is thermally connected to die 104 via thermal interface material 108. Cold plate 106 can include surface structure 114 on its top surface, which faces away from die 104. For example, surface structure 114 can be fins that increase a surface area for transferring heat to a fluid, such as air, water, or another liquid. Additionally or alternatively, the surface structure 114 on the top surface of cold plate 106 can include microstructure or nanostructure that provides improved heat transfer. For simplicity, the term “microstructure” is used to refer to the structure on the top surface of cold plate 106 regardless of whether this structure is on a millimeter, micrometer, and/or nanometer scale.

By integrating cold plate 106 into the packaging, packaged microchip 100 provides improved heat transfer compared to lidless microchips and lidded microchips. As discussed above, for lidless and lidded microchip designs, the cold plate is provided external to the packaging and is only provided after mounting the packaged microchip to a printed circuit board. Heat transfer is impeded for lidded microchips with an external cold plate due to the thermal resistance arising from the additional thermal interface material between the lid and the external cold plate. For lidless microchips, heat transfer is impeded by thickness variations in the thermal interface material between the die and the external cold plate. These thickness variations occur because the absence of a lid decreases the rigidity of the packaged microchip, resulting in increased warping of the die.

According to certain non-limiting examples, die 104 can use flip-chip technology to mount die 104 to substrate 102. In flip-chip technology, the microchip (or die) is mounted upside down (flipped) onto the substrate. Instead of traditional wire bonding, electrical connections are made through small bumps of solder or conductive material on the chip's surface. Die 104 can be a silicon chip on which an integrated circuit has been fabricated, and the silicon chip can have metallic pads on its surface where solder bumps are applied. Substrate 102 can provide mechanical support and electrical connections. Further, substrate 102 can have multiple metallization layers that consist of copper or gold and provide electrical pathways for signals and power.

Microbumps 112 can be created on pads of die 104. These bumps serve as the connection points to the substrate. Examples of materials for these bumps include lead-tin solder or newer, lead-free alternatives. Microbumps 112 can be a ball grid array (BGA).

FIG. 1B illustrates packaged microchip 100, such as in FIG. 1A, with cold plate cover 116 fixed to cold plate 106. Cold plate cover 116 can include inlet port 118 and outlet port 120, which enable a liquid, such as chilled water or another refrigerant, to flow through cold plate cover 116 thereby providing heat transfer to the liquid from cold plate 106 and from the cold plate cover 116.

According to certain non-limiting examples, the liquid can flow in through inlet port 118 through a space/cavity formed between cold plate 106 and surface structure 114, and then flow out through outlet port 120. For example, surface structure 114 can be a two-dimensional array of pillars, which increases the surface area for heat transfer from cold plate 106 to the liquid, and the liquid can flow around the pillars, exiting through outlet port 120.

In FIG. 1C, packaged microchip 100 is the same as in FIG. 1A, except the flange of cold plate 106 that extends to adhesive 110 on substrate 102 is replaced by stiffener ring 122 and cold plate 106 attaches to stiffener ring 122 via adhesive 124.

The rigidity provided by a stiffener ring 122 or a flange of cold plate 106 mitigates warping of die 104, enabling a more uniform distance between the thermal-interface surface of die 104 and the thermal-interface surface of cold plate 106, which in turn provides a more uniform thickness for thermal interface material 108. The uniform thickness of the thermal interface material 108 prevents thicker regions of thermal interface material 108, which have higher thermal resistance. Thus, by reducing warping of die 104 thermal conduction away from die 104 can be improved.

Improved thermal conduction is realized when thermal interface material 108 is uniformly thin because cold plate 106 has better thermal conduction properties than thermal interface material 108. Thus, a thinner thermal interface material 108 results in less thermal resistance for the combined heat-removal system (e.g., the combination of cold plate 106 and thermal interface material 108). For example, if the minimum thickness of thermal interface material 108 is specified as 100 μm, then warping would result in some portion of thermal interface material 108 being thicker.

For example, thermal mismatches between a die and a substrate, which can be affected by variations in die thickness, sizes, and packaging materials, can result in die and/or substrate warping. This warping can cause changes in TIM thickness and variations between the center and edges of the die. Such variations can lead to a substantial increase in average thermal resistance-more than 20% compared to scenarios where the thermal interface material (TIM) maintains a uniform thickness across the die.

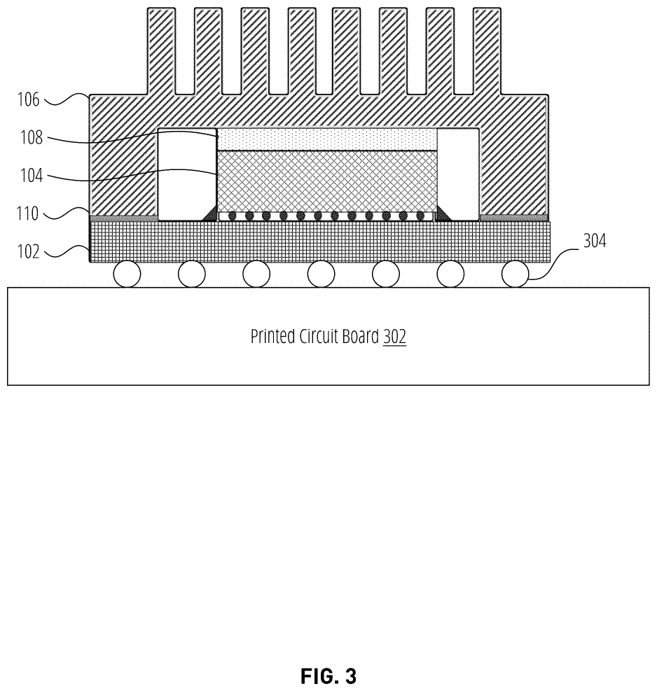

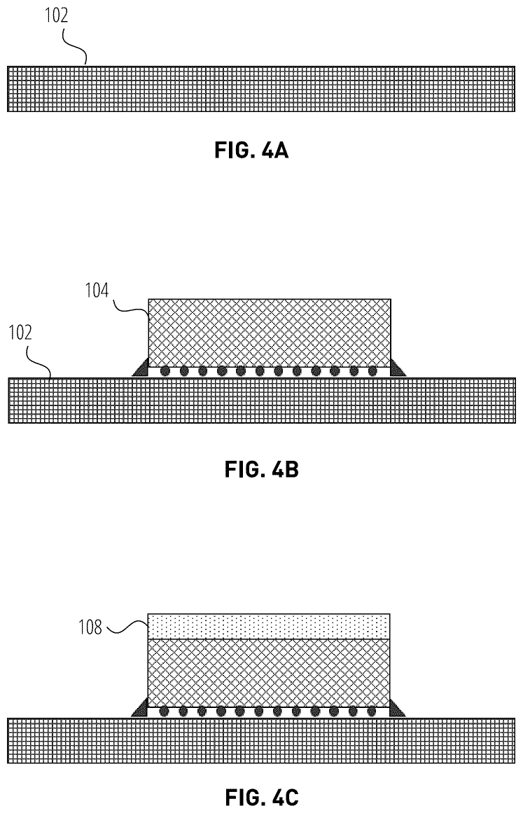

FIG. 2A and FIG. 2B illustrates packaged microchip 100, as in FIG. 1A, wherein cold plate 106 includes channel 202 through which a liquid can flow to provide heat transfer to the liquid from cold plate 106. FIG. 2A shows a cutaway side view. The liquid can be a refrigerant. The refrigerant enters through inlet 204 and passes through channel 202, where heat is transferred to the refrigerant before the refrigerant exits via outlet 206.

FIG. 2B shows a cutaway top view of cold plate 106, illustrating an example in which channel 202 provides a serpentine path for the refrigerant through cold plate 106.

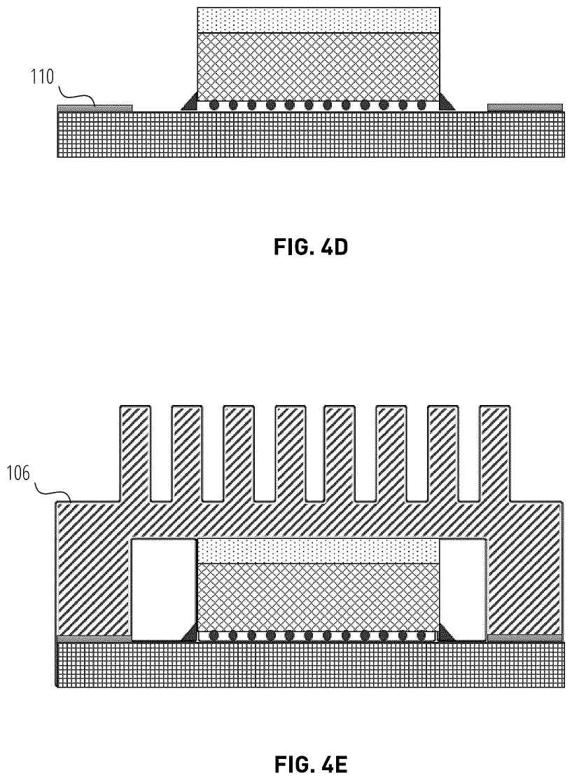

FIG. 3 illustrates mounting packaged microchip 100 to printed circuit board 302. As discussed above, cold plate 106 is integrated with the chip packaging, such that cold plate 106 is part of packaged microchip 100 prior to mounting it to printed circuit board 302. Therefore, a cold plate is not applied/fixed to packaged microchip 100 after the die has been mounted to printed circuit board 302. FIG. 3 shows that packaged microchip 100 is mounted to printed circuit board 302 using solder balls 304. According to certain non-limiting examples, cold plate cover 116 can be connected to packaged microchip 100 after solder reflow.

According to certain non-limiting examples, packaged microchip 100 can be mounted to 302 using a reflow process that includes aligning solder balls 304 with the metal pads of printed circuit board 302, heating the assembly to melt solder balls 304, and cooling the assembly to complete the reflow of solder balls 304.

Mounting a chip to a printed circuit board (PCB) can provide proper electrical connections and mechanical stability. The PCB can have pads and traces to accommodate the chip, wherein the PCB is designed with pads arranged in a grid pattern corresponding to the solder balls on the ball grid array (BGA) chip. Each pad is sized and positioned to match the ball dimensions for effective soldering. Solder balls are pre-attached to the BGA chip during manufacturing. These balls can be, e.g., lead-free solder or lead-based solder, depending on the application. A pick-and-place machine picks up the BGA chip and positions it over the PCB. Precise alignment ensures that each solder ball sits directly over its corresponding pad on the PCB.

After placement, the PCB assembly can be placed in a reflow oven. The reflow process can include preheating, soaking, and reflow of the PCB assembly. During preheating, the assembly is gradually heated to remove moisture and prepare the solder for melting. During soaking, the temperature is held steady for a short duration to allow even heating and activation of the flux within the solder balls. During reflow, the temperature is raised to the solder melting point (e.g., about 217° C. for leaded solder) where the solder balls melt, forming a liquid solder connection between the chip and the PCB pads. Next, the assembly is cooled to solidify the solder joints. Gradually cooling helps to avoid thermal shock and to ensure reliable connections.

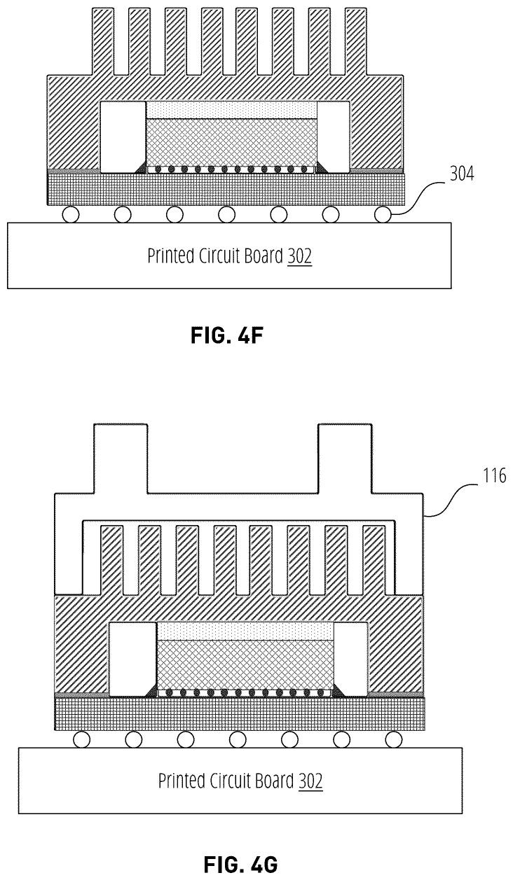

FIGS. 4A-G illustrates packaged microchip 100 at various points during assembly. FIG. 4A shows substrate 102 before any other components of packaged microchip 100 have been added.

FIG. 4B shows the combination of substrate 102 and die 104, after mounting die 104 to substrate 102.

According to certain non-limiting examples, the assembly of die 104 on substrate 102 can be performed using flip-chip technology. Flip-chip technology is a packaging technique used to mount microchips directly onto substrates, allowing for high-performance connections.

In flip-chip technology, the microchip (or die) is mounted upside down (flipped) onto the substrate, which contrasts with wire-bonding electrical connections. For example, the microchip (which herein is also referred to as a die) can be a silicon chip on which an integrated circuit has been fabricated. The microchip/die has metallic pads on its surface where solder bumps (e.g., microbumps 112) are applied. The substrate can be, e.g., a material like a glass-reinforced epoxy laminate material (e.g., FR4), ceramic, or other high-performance materials. The substrate provides mechanical support and electrical connections. Further, the substrate can include metallization layers, which can be, e.g., copper or gold, providing pathways to the die for signals and power.

Microbumps 112 can be solder bumps that are created on the pads of the die, providing connection points to the substrate. To mount the die on the substrate, the die can aligned over the substrate, ensuring that the solder bumps are correctly positioned over the corresponding pads on the substrate. Heat is then applied to melt the solder bumps, allowing them to flow and create strong electrical and mechanical connections between the die and the substrate. The assembly is then cooled, solidifying the solder and forming robust connections.

FIG. 4C shows packaged microchip 100 after a thermal interface material (TIM) has been applied on top of the die. Here, thermal interface material 108 is shown on the surface of die 104 that faces away from the substrate. The surface of die 104 facing away from the substrate can be referred to as the thermal-interface surface, and the surface of die 104 that faces the substrate can be referred to as the substrate surface.

TIMs can provide thermal conductivity between the die and the cold plate. Examples, of materials that can be used as a TIM, include, but are not limited to: thermal grease (or thermal paste), thermal pads, phase change materials (PCMs), conductive adhesives, liquid metal TIMs, and thermal conductive tapes. Thermal grease can be a viscous compound that fills microscopic gaps between surfaces. Thermal grease can be silicone-based, with metal oxides (like zinc oxide or aluminum oxide) for enhanced thermal conductivity. Thermal pads can be solid or semi-solid pads made from materials like silicone or rubber. Thermal pads can be compressible, conforming to uneven surfaces. PCMs are materials that change phase (from solid to liquid) at a specific temperature, enhancing thermal contact and can have high thermal conductivity when in liquid form. Conductive adhesives provide two functionalities because, in addition to providing thermal conductivity, the conductive adhesives can bond components together. Conductive adhesives can be epoxy-based with embedded metallic fillers (like silver or aluminum). Liquid Metal TIMs are composed of liquid metal alloys (e.g., gallium-based) and provide good thermal conductivity at the risk of increased corrosion. Thermal conductive tapes are adhesive tapes that have thermal conductive properties.

FIG. 4D shows packaged microchip 100 after an adhesive has been applied on the substrate. Here, adhesive 110 has been applied to a portion of substrate 102 surrounding die 104. Adhesive 110 can be selected to have a high strength. For example, cold plate 106 can be connected to ports for a liquid to flow through or around cold plate 106. These ports can connect to liquid conduits (e.g., water tubes or hoses), resulting in stress to adhesive 110. Thus, adhesive 110 can be selected to have a high enough strength to withstand anticipated stresses/forces applied between cold plate 106 and substrate 102.

FIG. 4E shows packaged microchip 100 after the cold plate has been connected to the substrate by the adhesive. Here, adhesive 110 fixes cold plate 106 to substrate 102.

Cold plates can provide cooling for microchips, such as compute dies used in high-performance computing. Cold plates can facilitate efficient heat transfer from the die to a cooling medium, such as a liquid refrigerant or air.

According to certain non-limiting examples, cold plate 106 can be a monolithic mechanical member fabricated out of a metal, such as copper, aluminum, nickel-plated copper, or stainless steel. Copper can have a thermal conductivity of about 400 W/m·K, making it highly effective for heat transfer. Aluminum is lighter than copper and can have a thermal conductivity of about 235 W/m. K, making it effective for heat transfer but not as effective as copper. Nickel-plated copper can be used to avoid the corrosion and oxidation of copper. Nickel-plated copper combines copper's high thermal conductivity with nickel's corrosion resistance, which is beneficial for liquid cooling applications. Stainless steel has a lower thermal conductivity than copper and aluminum but can provide excellent corrosion resistance.

According to certain non-limiting examples, cold plate 106 can include structures that enhance heat transfer, e.g., by increasing the surface area for heat transfer or by providing channels through which a liquid such as water with high thermal conductivity and high specific heat can flow. For example, cold plates can incorporate fins or pillars, which are extended surfaces that increase the surface area available for heat transfer. Fins (and pillars) can enhance heat dissipation, especially in air-cooled applications. The fins can be made from the same material as the plate or different materials for optimized performance. Further, cold plates can include internal channels through which coolant flows. These channels can be designed in various configurations (straight, serpentine, etc.) to maximize fluid contact with the cold plate surface, thereby enhancing liquid cooling efficiency by increasing the heat transfer area and improving fluid flow dynamics. As an additional non-limiting example, cold plates can have an integrated heat sink (e.g., multiple fins or plates that dissipate heat through convection and radiation).

Cold plate 106 contacts thermal interface material 108 allowing heat to efficiently flow from die 104 to cold plate 106. By providing a thermal interface material (TIM) between the die, the TIM can fill microscopic gaps to improve thermal conduction and reduce thermal resistance.

FIG. 4E shows the mounting of packaged microchip 100 to the printed circuit board 302, after the packaging processes have been completed. The cold plate has been connected to the substrate using adhesive. As discussed above with reference to FIG. 3, solder ball 304 attached to substrate 102 can be aligned to metal pads on printed circuit board 302, and the assembly can be heated to reflow the solder. Note, cold plate 106 is integrated with the chip packaging, such that cold plate 106 is part of packaged microchip 100 prior to mounting packaged microchip 100 to printed circuit board 302.

FIG. 4G shows attaching cold plate cover 116 to cold plate 106 after solder reflow that mounts packaged microchip 100 to printed circuit board 302. Additionally or alternatively, cold plate cover 116 can be attached to cold plate 106 before solder reflow mounting packaged microchip 100 to printed circuit board 302.

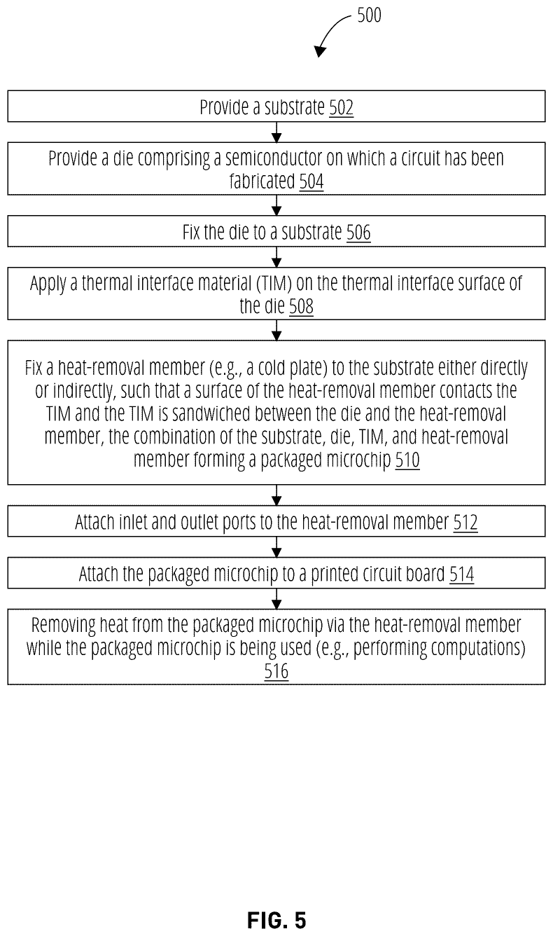

FIG. 5 illustrates an example method 500 for assembling a packaged microchip 100 with integrated cold plate. Although the example method 500 depicts a particular sequence of operations, the sequence may be altered without departing from the scope of the present disclosure. For example, some of the operations depicted may be performed in parallel or in a different sequence that does not materially affect the function of the method 500. In other examples, different components of an example device or system that implements the method 500 may perform functions at substantially the same time or in a specific sequence.

According to some examples, step 502 of the method includes providing a substrate. For example, substrate 102 can be provided as illustrated in FIG. 4A.

According to some examples, step 504 of the method includes providing a die comprising a semiconductor on which a circuit has been fabricated. For example, die 104 can be provided. According to certain non-limiting examples, die 104 can be fabricated on silicon using flip-chip technology.

According to some examples, step 506 of the method includes fixing the die to a substrate. For example, die 104 can be fixed to substrate 102, as illustrated in FIG. 4B.

According to some examples, step 508 of the method includes applying a thermal interface material (TIM) on the thermal-interface surface of the die. For example, thermal interface material 108 can be applied to the thermal interface side of die 104, as illustrated in FIG. 4C.

According to some examples, step 510 of the method includes fixing a heat-removal member (e.g., a cold plate) to the substrate either directly or indirectly. The surface of the heat-removal member contacts the TIM, and the TIM is sandwiched between the die and the heat-removal member. The combination of the substrate, die, TIM, and heat-removal member forms the packaged microchip. For example, in FIG. 1C, cold plate 106 is indirectly fixed to substrate 102 via adhesive 124, stiffener ring 122, and adhesive 110.

Alternatively, in FIG. 1A, cold plate 106 is directly fixed to substrate 102 via adhesive 110. In FIG. 1A, a flange of the cold plate 106 extends from the plain of the thermal-interface surface of cold plate 106 to adhesive 110 on substrate 102, enabling the cold plate 106 to be directly fixed to substrate 102 and providing increased rigidity for packaged microchip 100.

The rigidity provided by a stiffener ring 122 or a flange of cold plate 106 mitigates warping of die 104, enabling a more uniform distance between the thermal-interface surface of die 104 and the thermal-interface surface of cold plate 106, which in turn provides a more uniform thickness for thermal interface material 108. The uniform thickness of the thermal interface material 108 prevents thicker regions of thermal interface material 108, which have higher thermal resistance. Thus, by reducing warping of die 104, thermal conduction between cold plate 106 and die 104 can be improved.

According to some examples, step 512 of the method includes attaching inlet and outlet ports to the heat-removal member. For example, cold plate cover 116 having inlet port 118 and outlet port 120 can be attached as illustrated in FIG. 4G.

According to some examples, step 514 of the method includes attaching the packaged microchip to a printed circuit board. For example, printed circuit board 302 can be attached as illustrated in FIG. 4F.

According to some examples, step 516 of the method includes removing heat from the packaged microchip via the heat-removal member while the packaged microchip is being used (e.g., performing computations).

For clarity of explanation, in some instances, the present technology may be presented as including individual functional blocks including functional blocks comprising devices, device components, steps or routines in a method embodied in software, or combinations of hardware and software.

As described herein, in some aspects, the present technology relates to a packaged microchip, including: a substrate; a die including a circuit fabricated on a semiconductor, the die having a substrate surface and a thermal-interface surface on an opposite surface of the die from the substrate surface, the die being fixed to the substrate by the substrate surface of the die; a thermal interface material (TIM) arranged on the thermal-interface surface of the die; and a heat-removal member that is fixed to the substrate, the heat-removal member having a die surface, which faces the die, and a heat-dissipating surface, the die surface contacting the TIM such that the TIM is sandwiched between the die and the heat-removal member, the heat-removal member being monolithic, and being configured to remove heat from the die via heat transfer from the heat-removal member to a fluid.

In some aspects, the techniques described herein relate to a method for providing a packaged microchip, the method including: fixing a die to a substrate, the die including a circuit fabricated on a semiconductor, and the die having a substrate surface, which faces the substrate, and a thermal-interface surface on an opposite surface of the die from the substrate surface; applying a thermal interface material (TIM) on the thermal-interface surface of the die; fixing a heat-removal member to the substrate either directly or indirectly, the heat-removal member having a die surface, which faces the die, and a heat-dissipating surface, the die surface of the heat-removal member contacting the TIM, such that the TIM is sandwiched between the die and the heat-removal member, wherein the heat-removal member is a monolithic member that is configured to remove heat from the die via heat transfer from the heat-removal member to a fluid, and the packaged microchip includes a combination of the substrate, the die, the TIM, and the heat-removal member.

### Aspects:

The present technology includes computer-readable storage mediums for storing instructions, and systems for executing any one of the methods embodied in the instructions addressed in the aspects of the present technology presented below:

Clause 1. A packaged microchip, comprising: a substrate; a die comprising a circuit fabricated on a semiconductor, the die having a substrate surface and a thermal-interface surface on an opposite surface of the die from the substrate surface, the die being fixed to the substrate by the substrate surface of the die; a thermal interface material (TIM) arranged on the thermal-interface surface of the die; and a heat-removal member that is fixed to the substrate, the heat-removal member having a die surface, which faces the die, and a heat-dissipating surface, the die surface contacting the TIM such that the TIM is sandwiched between the die and the heat-removal member, the heat-removal member being monolithic, and being configured to remove heat from the die via heat transfer from the heat-removal member to a fluid.

Clause 2. The packaged microchip of clause 1, wherein the heat-dissipating surface of the heat-removal member has a microstructure.

Clause 3. The packaged microchip of clause 1 or clause 2, wherein the microstructure includes fins that are configured to transfer heat from the heat-removal member to the fluid, and the fluid is a gas or a liquid.

Clause 4. The packaged microchip of any of clause 1 through clause 3, wherein the heat-dissipating surface of the heat-removal member faces away from the die and contacts air outside the packaged microchip, when the microchip is in operation and is mounted to a printed circuit board.

Clause 5. The packaged microchip of any of clause 1 through clause 4, wherein the heat-removal member is a cold plate that includes a channel arranged to transfer heat from the heat-removal member to the fluid passing through the channel.

Clause 6. The packaged microchip of any of clause 1 through clause 5, further comprising: solder balls arranged on a surface of the substrate facing away from the die; wherein metallization layers in the substrate provide electrical pathways from the die to the solder balls.

Clause 7. The packaged microchip of any of clause 1 through clause 6, wherein a thickness of the TIM sandwiched between the die and the heat-removal member is less than 100 μm.

Clause 8. The packaged microchip of any of clause 1 through clause 7, wherein a thickness of the TIM sandwiched between the die and the heat-removal member is substantially uniform, deviating from an average thickness by less than 20%.

Clause 9. The packaged microchip of any of clause 1 through clause 8, further comprising: a cold plate cover that is fixed to the heat-removal member, wherein the cold plate cover provides a space through which the fluid flows to transfer heat from the heat-removal member.

Clause 10. The packaged microchip of any of clause 1 through clause 9, further comprising: a die lid that comprises the heat-removal member and a stiffening member, the stiffening member including a flange that extends in a direction normal to a plane of the substrate, the flange extending from the heat-removal member to the substrate and fixing the heat-removal member to the substrate.

Clause 11. The packaged microchip of clause 10, wherein the die lid is fixed to the substrate by an adhesive prior to attaching the packaged microchip to a printed circuit board.

Clause 12. The packaged microchip of clause 10, wherein the die lid hermetically seals the die between the die lid and the substrate.

Clause 13. A method for providing a packaged microchip, the method comprising: fixing a die to a substrate, the die comprising a circuit fabricated on a semiconductor, and the die having a substrate surface, which faces the substrate, and a thermal-interface surface on an opposite surface of the die from the substrate surface; applying a thermal interface material (TIM) on the thermal-interface surface of the die; fixing a heat-removal member to the substrate either directly or indirectly, the heat-removal member having a die surface, which faces the die, and a heat-dissipating surface, the die surface of the heat-removal member contacting the TIM, such that the TIM is sandwiched between the die and the heat-removal member, wherein the heat-removal member is a monolithic member that is configured to remove heat from the die via heat transfer from the heat-removal member to a fluid, and the packaged microchip comprises a combination of the substrate, the die, the TIM, and the heat-removal member.

Clause 14. The method of clause 13, further comprising mounting the packaged microchip to a printed circuit board, after the heat-removal member has been fixed to the substrate.

Clause 15. The method of clause 14, wherein the heat-dissipating surface of the heat-removal member is configured to contact air outside the packaged microchip, when the packaged microchip is mounted to the printed circuit board.

Clause 16. The method of any of clause 13 through clause 15, wherein the heat-dissipating surface of the heat-removal member has a microstructure.

Clause 17. The method of clause 16, wherein the microstructure includes fins that are configured to transfer heat from the heat-removal member to the fluid, and the fluid is a gas or a liquid.

Clause 18. The method of any of clause 13 through clause 17, wherein the heat-dissipating surface of the heat-removal member contacts air outside of the packaged microchip, when the packaged microchip is in operation and is mounted to a printed circuit board.

Clause 19. The method of any of clause 13 through clause 18, wherein the heat-removal member is a cold plate that includes a channel arranged to transfer heat from the heat-removal member to the fluid passing through the channel.

Clause 20. The method of clause 14, wherein the substrate includes solder balls arranged on a PCB surface of the substrate, which faces away from the die, and the substrate includes metallization layers providing electrical pathways from the die to the solder balls, and the method further includes that mounting the packaged microchip to the printed circuit board by aligning the packaged microchip with the printed circuit board and heating to reflow the solder balls.

Clause 21. The method of any of clause 13 through clause 20, wherein a thickness of the TIM sandwiched between the die and the heat-removal member is less than 100 μm.

Clause 22. The method of any of clause 13 through clause 21, wherein a thickness of the TIM sandwiched between the die and the heat-removal member is substantially uniform, deviating from an average thickness by less than 20%.

Clause 23. The method of any of clause 13 through clause 22, wherein the packaged microchip further includes a stiffening member that includes a flange in a direction normal to a surface of the substrate.

Clause 24. The method of clause 13, wherein the heat-removal member is fixed to the substrate by an adhesive prior to attaching the packaged microchip to a printed circuit board.

Clause 25. The method of clause 13, wherein fixing the heat-removal member to the substrate hermetically seals the die between the heat-removal member and the substrate.

What is claimed is:

1. A packaged microchip, comprising:
a substrate;
a die comprising a circuit fabricated on a semiconductor, the die having a substrate surface and a thermal-interface surface on an opposite surface of the die from the substrate surface, the die being fixed to the substrate by the substrate surface of the die;
a thermal interface material (TIM) arranged on the thermal-interface surface of the die; and
a heat-removal member that is fixed to the substrate, the heat-removal member having a die surface, which faces the die, and a heat-dissipating surface, the die surface contacting the TIM such that the TIM is sandwiched between the die and the heat-removal member, the heat-removal member being monolithic and being configured to remove heat from the die via heat transfer from the heat-removal member to a fluid.

2. The packaged microchip of claim 1, wherein the heat-dissipating surface of the heat-removal member includes surface structure.

3. The packaged microchip of claim 2, wherein the surface structure include fins that are configured to transfer heat from the heat-removal member to the fluid, and the fluid is a gas or a liquid.

4. The packaged microchip of claim 1, wherein the heat-dissipating surface of the heat-removal member faces away from the die and contacts air outside the packaged microchip, when the microchip is in operation and is mounted to a printed circuit board.

5. The packaged microchip of claim 1, wherein the heat-removal member is a cold plate that includes a channel arranged to transfer heat from the heat-removal member to the fluid passing through the channel.

6. The packaged microchip of claim 1, further comprising:
solder balls arranged on a surface of the substrate facing away from the die; wherein metallization layers in the substrate provide electrical pathways from the die to the solder balls.

7. The packaged microchip of claim 1, further comprising:
a cold plate cover that is fixed to the heat-removal member, wherein
the cold plate cover provides a space through which the fluid flows to transfer heat from the heat-removal member.

8. The packaged microchip of claim 1, further comprising:
a die lid that comprises the heat-removal member and a stiffening member, the stiffening member including a flange that extends in a direction normal to a plane of the substrate, the flange extending from the heat-removal member to the substrate and fixing the heat-removal member to the substrate.

9. The packaged microchip of claim 1, wherein the die heat-removal member is fixed to the substrate by an adhesive prior to attaching the packaged microchip to a printed circuit board.

10. The packaged microchip of claim 1, wherein the heat-removal member hermetically seals the die in a space between the heat-removal member and the substrate.

11. A method for providing a packaged microchip, the method comprising:
fixing a die to a substrate, the die comprising a circuit fabricated on a semiconductor, and the die having a substrate surface, which faces the substrate, and a thermal-interface surface on an opposite surface of the die from the substrate surface;
applying a thermal interface material (TIM) on the thermal-interface surface of the die;
fixing a heat-removal member to the substrate either directly or indirectly, the heat-removal member having a die surface, which faces the die, and a heat-dissipating surface, the die surface of the heat-removal member contacting the TIM, such that the TIM is sandwiched between the die and the heat-removal member, wherein
the heat-removal member is a monolithic member that is configured to remove heat from the die via heat transfer from the heat-removal member to a fluid, and
the packaged microchip comprises a combination of the substrate, the die, the TIM, and the heat-removal member.

12. The method of claim 11, further comprising mounting the packaged microchip to a printed circuit board, after the heat-removal member has been fixed to the substrate.

13. The method of claim 12, wherein the heat-dissipating surface of the heat-removal member is configured to contact air outside the packaged microchip, when the packaged microchip is mounted to the printed circuit board.

14. The method of claim 11, wherein the heat-dissipating surface of the heat-removal member includes surface structure.

15. The method of claim 14, wherein the surface structure include fins that are configured to transfer heat from the heat-removal member to the fluid, and the fluid is a gas or a liquid.

16. The method of claim 11, wherein the heat-dissipating surface of the heat-removal member contacts air outside of the packaged microchip, when the packaged microchip is in operation and is mounted to a printed circuit board.

17. The method of claim 11, wherein the heat-removal member is a cold plate that includes a channel arranged to transfer heat from the heat-removal member to the fluid passing through the channel.

18. The method of claim 12, wherein
the substrate includes solder balls arranged on a PCB surface of the substrate, the PCB surface facing the printed circuit board, and the substrate includes metallization layers providing electrical pathways from the die to the solder balls, and
the method further includes mounting the packaged microchip to the printed circuit board by aligning the packaged microchip with the printed circuit board and heating a combination of the packaged microchip and the printed circuit board to reflow the solder balls.

19. The method of claim 11, wherein the heat-removal member is fixed to the substrate by an adhesive prior to attaching the packaged microchip to a printed circuit board.

20. The method of claim 11, wherein fixing the heat-removal member to the substrate hermetically seals the die between the heat-removal member and the substrate.
